(19) United States
(12) Patent Application Publication
(10) Pub. No.: US 2011/0120221 A1
(43) Pub. Date: May 26, 2011

(54) MEMS SENSOR, METHOD OF MANUFACTURING THEREOF, AND ELECTRONIC APPARATUS

(75) Inventor: Mitsuhiro Yoda, Shiojiri (JP)

(73) Assignee: Seiko Epson Corporation, Tokyo (JP)

(21) Appl. No.: 12/948,055

(22) Filed: Nov. 17, 2010

(30) Foreign Application Priority Data
Nov. 25, 2009 (JP) 2009-267794

(51) Int. Cl. G01P 15/125; H05K 3/00

(52) U.S. Cl. 73/514.32; 29/829

(57) ABSTRACT

A MEMS sensor includes: a fixed portion; an elastically deformable portion; a movable weight portion coupled to the fixed portion via the elastically deformable portion, the movable weight portion including a coupling portion; a plurality of fixed electrode portions arranged in a first direction and protruding in a second direction perpendicular to the first direction; and a plurality of movable electrode portions protruding from the coupling portion in the second direction, provided to respectively face the plurality of fixed electrode portions, and arranged in the first direction, wherein the movable weight portion has an additional weight portion connected to the coupling portion.

### BACKGROUND

1. Technical Field

The present invention relates to a MEMS (Micro Electro Mechanical Systems) sensor, a method of manufacturing thereof, an electronic apparatus, and the like.

2. Related Art

In typical electrostatic capacitive MEMS acceleration sensors, a change in capacitance composed of comb-teeth electrodes (electrodes arranged in a comb-teeth shape; specifically for example, a plurality of sets of electrodes in each set of which the electrodes face each other are provided in a predetermined direction) is detected to thereby determine a change in acceleration as a physical quantity.

In the MEMS acceleration sensor, noise reduction is especially an important subject. For reducing noise (that is, improving detection sensitivity) of the electrostatic capacitive MEMS acceleration sensor, it is effective to increase the mass of a movable weight portion.

A sensitivity S of the sensor is expressed by S=C0/d0·(M/K) [F/(m/sec²)] where C0 is the entire capacitance of electrode capacitors formed of a plurality of movable/fixed electrodes; K is the spring constant of an elastically deformable portion 0; d0 is an inter-electrode gap; and M is the mass of a movable portion. That is, the sensitivity is improved as the mass M of the movable portion increases.

The movable electrode portion and the fixed electrode portion are provided to face each other where the height is h; the facing length of the electrodes is r; and the inter-electrode gap is d0. When the gap d0 of the capacitor changes by the movement of the movable electrode portion, gas between the electrodes moves vertically. At the time, the viscosity of the gas (air) generates damping (action to stop the vibration (movement) of the movable electrode portion) with respect to the movement of the movable electrode portion. A damping coefficient D representing the magnitude of damping can be expressed by D=n·μ·r(h/d0)³ [N·sec/m] where n is the number of electrode pairs (the number of sets of electrode pairs composed of the fixed electrode portion and the movable electrode portion); and μ is the viscosity coefficient of gas. That is, the damping coefficient D is proportional to the cube of the height h of the electrode portion and proportional to the inverse of the cube of the gap d0.

Force acts on the movable electrode portion due to the Brownian motion of the gas, which serves as the Brownian noise equivalent acceleration. The Brownian noise (BNEA) is expressed by BNEA=(√4k_{B}TD))/M[(m/sec²)/√Hz] where k_{B} is the Boltzmann coefficient; and T is the absolute temperature. The numerator of the equation is proportional to the square root of the damping coefficient D that is proportional to the cube of the height h of the movable electrode portion.

In JP-A-11-248739, a weight portion is provided in a different layer from a movable electrode to increase the mass of a movable portion. However, a fixed electrode portion and the movable electrode portion face each other in a stacked direction of a stacked structure, which is fundamentally different from the structure of the invention in which a fixed electrode portion and a movable electrode portion are located in the same layer.

Miniaturization of MEMS sensors used for applications of attitude control or the like of aircrafts, rockets, vehicles, robots, various electronic apparatuses, the human body, or the like is demanded, and its occupied area is restricted. On the other hand, improvement in detection accuracy is demanded by increasing the capacitance formed of an electrode pair of a movable electrode portion and a fixed electrode portion and by increasing the mass of a movable portion including the movable electrode portion and the movable weight portion.

The only way to increase the mass of the movable portion in the limited occupied area is to increase the height of the movable electrode portion and the movable weight portion. However, this increases the Brownian noise. On the other hand, the only way to increase the capacitance in the limited occupied area is to increase the length of the movable electrode portion protruding from the movable weight portion. However, this reduces the mass of the movable portion, resulting in a poor sensitivity.

### SUMMARY

An advantage of some aspects of the invention is to provide a MEMS sensor that can improve detection accuracy, a method of manufacturing thereof, and an electronic apparatus.

A MEMS sensor according to an aspect of the invention includes: a fixed portion; an elastically deformable portion; a movable weight portion coupled to the fixed portion via the elastically deformable portion and having a hollow portion formed therearound; a plurality of fixed electrode portions secured to the fixed portion to be arranged in a first direction and protruding along a second direction perpendicular to the first direction; and a plurality of movable electrode portions protrudingly formed from the movable weight portion along the second direction, provided to respectively face the plurality of fixed electrode portions, and arranged along the first direction, wherein the movable weight portion has a coupling portion formed in the same layer as the plurality of movable electrode portions and coupling the plurality of movable electrode portions, and an additional weight portion formed in a different layer from the plurality of movable electrode portions and the coupling portion and connected to the coupling portion.

In another aspect of the invention, a MEMS sensor includes: a fixed portion; an elastically deformable portion; a movable weight portion coupled to the fixed portion via the elastically deformable portion, the movable weight portion including a coupling portion; a plurality of fixed electrode portions arranged in a first direction and protruding in a second direction perpendicular to the first direction; and a plurality of movable electrode portions protruding from the coupling portion in the second direction, provided to respectively face the plurality of fixed electrode portions, and arranged in the first direction, wherein the movable weight portion has an additional weight portion connected to the coupling portion.

According to the aspect of the invention, at least one paradoxical need among a reduction in occupied area, an increase in capacitance, a reduction in the Brownian noise, an increase in mass of the movable portion, and the like can be satisfied in a balanced manner to improve detection accuracy.

First, as the background of the invention, a large capacitance needs to be secured in the restricted occupied area of the region including the coupling portion and the plurality of movable electrode portions. Since the electrode height cannot be increased because of the measures for the Brownian noise, the protruding length (length along the second direction) of the movable electrode portion protruding from the coupling portion needs to be increased. This increases an area occupied by the movable electrode having a comb-teeth shape in the restricted occupied area, while decreasing the area of the coupling portion.

In the aspect of the invention, for increasing the mass of the movable weight portion in the restrictions described above, the additional weight portion formed in a different layer from the plurality of movable electrode portions and the coupling portion is disposed, and the additional weight portion is connected to the coupling portion. Thus, even when the height of the movable electrode portion is not increased in view of the measures for the Brownian noise, or even when the protruding length of the movable electrode portion is increased because of the need for securing the capacitance, the mass of the movable weight portion is increased due to the additional weight portion, whereby detection accuracy can be improved.

In the aspect of the invention, the MEMS sensor can further have a first connection portion connecting the additional weight portion with the coupling portion. In this case, the hollow portion can extend to a region between the plurality of movable electrode portions and the additional weight portion in a third direction perpendicular to the first direction and the second direction and excluding the first connection portion. With this configuration, both edges of the movable electrode portion in the height direction (third direction) are opened, making it possible to allow gas between the electrodes to escape in the third direction to reduce the Brownian noise. Thus, detection accuracy is further improved.

In the aspect of the invention, the MEMS sensor can further have a second connection portion connecting at least one of the plurality of movable electrode portions with the additional weight portion. In this case, since the hollow portion extends to a region between the plurality of movable electrode portions and the additional weight portion in the third direction and excluding the first connection portion and the second connection portion, the Brownian noise can be reduced similarly, whereby detection accuracy is improved.

In the aspect of the invention, a width of the additional weight portion in a longitudinal section in the second direction can be greater than a width of the coupling portion in the longitudinal section in the second direction. With this configuration, the coupling portion and the plurality of movable electrode portions are formed in a fish-bone shape as shown in FIG. 1, so that the mass of that portion is greatly reduced. However, the mass of the movable weight portion is increased due to the additional weight portion, whereby detection accuracy can be improved.

In the aspect of the invention, the movable electrode portion protrudes from both edges of the coupling portion in the second direction, and a width of the additional weight portion in a longitudinal section in the second direction is smaller than a length in the second direction from an end of the movable electrode portion protruding from one edge of the coupling portion to an end of the movable electrode portion protruding from the other edge of the coupling portion. In this manner, since the additional weight portion can contribute to increasing the movable weight portion in a range falling within the occupied area of the coupling portion and the plurality of movable electrode portions, sensitivity is improved.

In the aspect of the invention, a height of the additional weight portion in a longitudinal section in the second direction can be greater than a height of the coupling portion in the longitudinal section in the second direction. The height of the additional weight portion does not increase the occupied area and has nothing to do with damping. Therefore, the additional weight portion can contribute to increasing the movable weight portion in a range falling within the occupied area of the coupling portion and the plurality of movable electrode portions, whereby sensitivity is improved.

In the aspect of the invention, the elastically deformable portion can couple the fixed portion with the additional weight portion. The elastically deformable portion may couple the fixed portion with the coupling portion. However, by coupling the fixed portion with the additional weight portion, the additional weight portion at which the center of gravity of the movable weight portion is positioned is supported by the elastically deformable portion. Therefore, even when force other than that in the detected direction (first direction) acts on the movable weight portion, displacement other than that in the first direction, such as rolling, can be reduced. Thus, detection accuracy is further improved.

In the aspect of the invention, when a direction perpendicular to the first direction and the second direction is defined as a third direction, one of the fixed electrode portion and the movable electrode portion is longer in the third direction than the other. With this configuration, even when force other than that in the detected direction (first direction) acts on the movable weight portion, and displacement other than that in the first direction, such as rolling, acts on the movable weight portion, the facing area of the electrode pair formed of the movable electrode portion and the fixed electrode portion does not change. Thus, noise caused by rolling or the like can be reduced, whereby detection accuracy is improved.

In the aspect of the invention, one of the plurality of fixed electrode portions and the plurality of movable electrode portions each can have an upper margin portion and a lower margin portion respectively protruding upward and downward beyond the other in the third direction, and partially have a region where a protruding amount of the lower margin portion is greater than a protruding amount of the upper margin portion.

This is considering deflection due to the own weight of the movable weight portion and/or the movable electrode portion. As design values, the margin amount of the lower margin portion is set to be greater than the margin amount of the upper margin portion. As a result of this setting, at a maximum deflection point due to the own weight of the movable weight portion and/or the movable electrode portion, the upper margin amount can be nearly equal to the lower margin amount. The maximum deflection point due to the own weight of the movable weight portion is presumably the position furthest from the elastically deformable portion. The maximum deflection point due to the own weight of the movable electrode portion is presumably a free end thereof furthest from a base end at which the movable electrode portion is coupled to the coupling portion. At a portion with a small deflection due to its own weight, the margin amount of the lower margin portion remains greater than the margin amount of the upper margin portion in accordance with the design values. Also at the portion with a small deflection, the margin amounts may be set so that one of the upper margin portion and the lower margin portion of the fixed electrode portion faces the movable electrode portion even if the movable electrode portion is displaced by rolling or the like in the vertical direction.

An electronic apparatus according to a still another aspect of the invention includes any of the MEMS sensors described above. Since the MEMS sensor according to the aspects of the invention can improve detection accuracy as described above, also an electronic apparatus mounting the MEMS sensor can enjoy the similar effects, making it possible to accurately realize attitude control of an electronic apparatus itself mounting the MEMS sensor, such as aircrafts, rockets, vehicles, or robots, or attitude control of the human body or the like mounting the electronic apparatus.

A method of manufacturing a MEMS sensor according to a still further aspect of the invention is a method of manufacturing a MEMS sensor having a fixed portion, an elastically deformable portion, a movable weight portion coupled to the fixed portion via the elastically deformable portion and having a hollow portion formed therearound, a plurality of fixed electrode portions secured to the fixed portion to be arranged along a first direction and protruding along a second direction perpendicular to the first direction, and a plurality of movable electrode portions protrudingly formed from the movable weight portion along the second direction, provided to respectively face the plurality of fixed electrode portions, and arranged along the first direction. The method includes: as a first step, etching a functional layer of a supporting substrate on which an intermediate layer and the functional layer are sequentially stacked, to thereby shape respective outlines, as viewed in plan, of the fixed portion, the elastically deformable portion, the plurality of fixed electrode portions, the plurality of movable electrode portions, and a coupling portion connecting the plurality of movable electrode portions, all formed of the functional layer; as a second step, etching the supporting substrate to thereby shape respective outlines, as viewed from the back side, of the fixed portion and an additional weight portion connected to the coupling portion, both formed of the supporting substrate; and as a third step after the first step and the second step, isotropically etching the intermediate layer other than the intermediate layer to be left in a region of a connection portion connecting the coupling portion with the additional weight portion and in a region of the fixed portion.

In a yet further another aspect of the invention, a method of manufacturing a MEMS sensor includes: preparing a supporting substrate having an intermediate layer and a functional layer stacked on the intermediate layer; applying etching to the supporting substrate to form a first hollow portion from a surface of the functional layer to a surface of the intermediate layer, to thereby define a fixed portion, a movable weight portion, an elastically deformable portion coupling the fixed portion with the movable weight portion, a fixed electrode portion, and a movable electrode portion facing the fixed electrode portion and protruding from the movable weight portion; etching the supporting substrate from a surface of the supporting substrate opposite to the surface where the intermediate layer and the functional layer are formed to form a second hollow portion at a position overlapping the first hollow portion as viewed in plan, to thereby define an additional weight portion; and etching the intermediate layer via at least one of the first hollow portion and the second hollow portion, to thereby form a first connection portion connecting the movable weight portion with the additional weight portion.

According to the first to third steps, the MEMS sensor according to the aspects of the invention can be preferably manufactured. The first step and the second step may be in either order.

### BRIEF DESCRIPTION OF THE DRAWINGS

The invention will be described with reference to the accompanying drawings, wherein like numbers reference like elements.

FIG. 1 is a plan view of a MEMS sensor (one-axis acceleration sensor) according to a first embodiment of the invention.

FIG. 2 is a longitudinal sectional view of the MEMS sensor including movable electrode portions in FIG. 1.

FIG. 3 is a longitudinal sectional view of a MEMS sensor to which second connection portions are added.

FIG. 4 is a longitudinal sectional view of the MEMS sensor including an elastically deformable portion in FIG. 1.

FIG. 5 shows the height relationship between the movable electrode portion and a fixed electrode portion in FIG. 1.

FIG. 6 shows a configuration example of a circuit portion of an electrostatic capacitive acceleration sensor.

FIGS. 7A to 7C explain exemplary configuration and operation of a Q/V conversion circuit.

FIGS. 8A to 8H show the manufacturing process of the MEMS sensor shown in FIG. 1.

FIG. 9 is a schematic sectional view of a sensor including an upper lid and a lower lid.

FIG. 10 is a plan view of a two-axis acceleration sensor according to a second embodiment of the invention.

FIG. 11 is a plan view of a gyro sensor according to a third embodiment of the invention.

### DESCRIPTION OF EXEMPLARY EMBODIMENTS

Hereinafter, preferred embodiments of the invention will be described in detail. The embodiments described below do not unduly limit the contents of the invention set forth in the claims. Also, not all of the configurations described in the embodiments may necessarily be indispensable as solving means of the invention.

### 1. First Embodiment

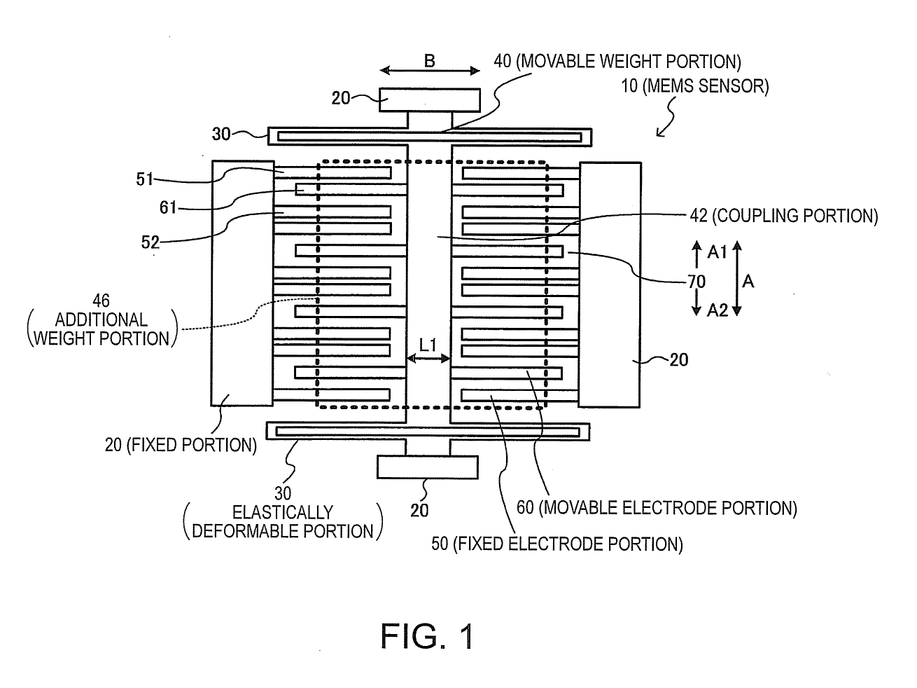

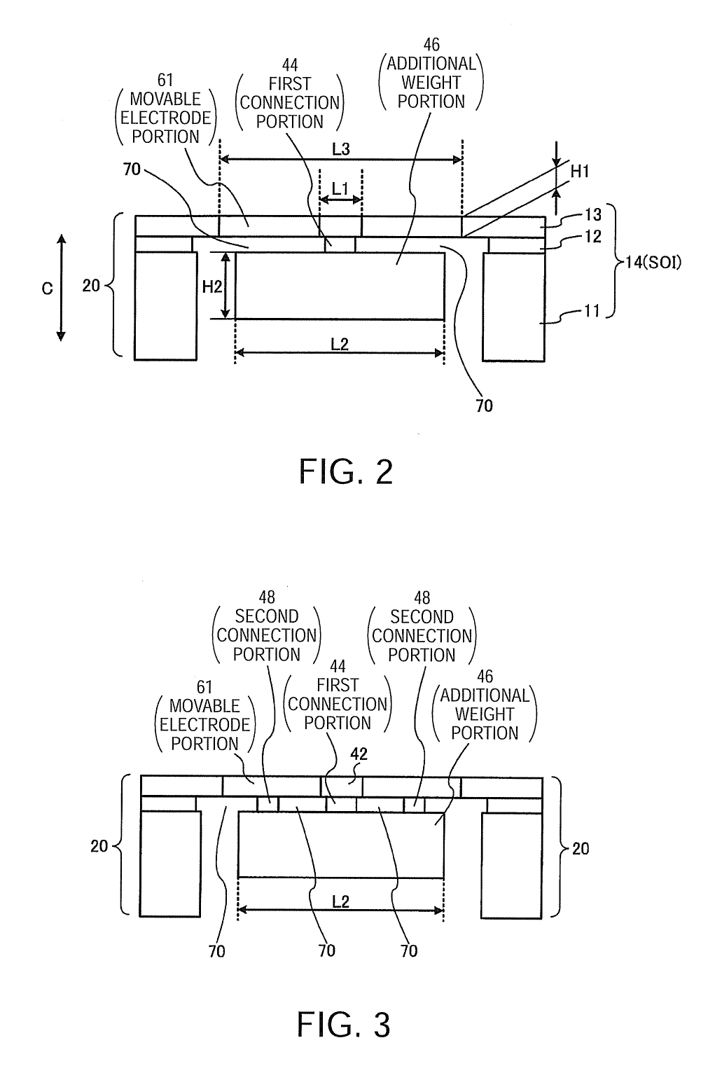

FIG. 1 is a plan view showing an exemplary structure of a MEMS sensor (electrostatic capacitive MEMS acceleration sensor in this case) according to a first embodiment of the invention. FIG. 2 is a longitudinal sectional view of the MEMS sensor including movable electrode portions in FIG. 1.

### Overall Configuration

In the following description, although an SOI (Silicon On Insulator) substrate 14, for example, can be used for a supporting substrate 11, an intermediate layer 12, and a functional layer 13 as the basic stacked structure of the MEMS sensor 10 shown in FIG. 2, this is not restrictive. The embodiment uses the SOI substrate 14 in which the supporting substrate 11 is silicon; the intermediate layer 12 is SiO₂; and the functional layer 13 is silicon as an active layer of the SOI substrate 14. In the embodiment, the functional layer 13 is doped with an impurity, so that a conductivity function as a fixed electrode or a movable electrode is assured. Regardless of using or not using the SOI substrate 14, the embodiment is not limited to the case of using the material itself of the functional layer 13 as an electrode, and a conductive layer may be disposed in the outermost layer of the functional layer 13. In such case, an insulating layer may be disposed as an under layer of the conductive layer to insulate between the functional layer 13 and the conductive layer. Any material can be used for the intermediate layer 12 as long as it is suitable for isotropic etching, and the material is not necessarily limited to an insulating material. The supporting substrate 11 can be made of any material as long as it has a supporting function.

As shown in FIG. 1, the MEMS sensor 10 can have fixed portions 20, elastically deformable portions 30, a movable weight portion 40, a plurality of fixed electrode portions 50, and a plurality of movable electrode portions 60. The fixed portion 20 can be formed in a frame shape so as to surround the elastically deformable portions 30, the movable weight portion 40, the plurality of fixed electrode portions 50, and the plurality of movable electrode portions 60 from all four sides. The movable weight portion 40 is coupled to the fixed portions 20 via the elastically deformable portions 30, and has hollow portions 70 formed therearound. The plurality of fixed electrode portions 50 are secured to the fixed portion 20 to be arranged along a first direction A, and protrude along a second direction B perpendicular to the first direction A. The plurality of movable electrode portions 60 are protrudingly formed from the movable weight portion 40 along the second direction B, provided to respectively face the plurality of fixed electrode portions 50, and arranged along the first direction A.

In the embodiment as shown in FIG. 1, two fixed electrode portions 51 and 52 are provided relative to one movable electrode portion 61 on both sides thereof in the first direction A, for example. When the movable weight portion 40 moves in the first direction A by inertial force, inter-electrode gaps on both sides of one movable electrode portion 60 fluctuate. Therefore, by detecting the fluctuations in the inter-electrode gaps as capacitance changes, the direction and magnitude of the inertial force can be detected. In this sense, the MEMS sensor 10 can also be referred to as an inertial sensor.

Specifically, when the movable weight portion 40 moves in a direction of an arrow A1 in FIG. 1, the inter-electrode gap between the movable electrode portion 61 and the fixed electrode portion 51 is narrowed, and the inter-electrode gap between the movable electrode portion 61 and the fixed electrode portion 52 is widened. On the contrary, when the movable weight portion 40 moves in a direction of an arrow A2 in FIG. 1, the inter-electrode gap between the movable electrode portion 61 and the fixed electrode portion 51 is widened, and the inter-electrode gap between the movable electrode portion 61 and the fixed electrode portion 52 is narrowed. The changes in the inter-electrode gaps can be detected as capacitance changes. That is, the movable electrode portion 61 is one of capacitive elements, while each of the fixed electrode portions 51 and 52 is the other capacitive element. This is not restrictive, and one fixed electrode portion may be disposed on one side of the movable electrode portion 61. In this case, however, detection sensitivity is lower than that of the embodiment.

### Movable Weight Portion

The movable weight portion 40 has a coupling portion 42 formed in the functional layer 13 that is the same layer as the plurality of movable electrode portions 60 and coupling the plurality of movable electrode portions 60. In the embodiment where inertial force in a one-axis direction (that is, the first direction A) is detected, the plurality of movable electrode portions 60 are protrudingly formed on both sides of the coupling portion 42. The coupling portion 42 and the plurality of movable electrode portions 60 present a fish-bone shape as viewed in plan, and the coupling portion 42 corresponds to the backbone.

The fish-bone shape is needed because of the following restrictions. First, there is a need for size reduction of the MEMS sensor 10, so that the occupied area including the coupling portion 42 and the plurality of movable electrode portions 60 must be reduced. Second, a large capacitance needs to be secured for improving the S/N ratio. Since the electrode height cannot be increased because of the measures for the Brownian noise, the protruding length (length along the second direction) of the movable electrode portion 60 needs to be increased. Because of the first and second needs, a width L1 of the coupling portion 42 is reduced, and the protruding length (length along the second direction) of the movable electrode portion 60 is increased, resulting in the fish-bone shape as a whole.

In this case, if the movable weight portion 40 is formed only of the coupling portion 42, the mass is apparently insufficient. Since the plurality of movable electrode portions 60 that largely occupy the occupied area of the fish-bone shape are formed in a comb-teeth shape, the entire mass cannot be increased even when the mass of the plurality of movable electrode portions 60 is added to the coupling portion 42. In this type of the MEMS sensor (inertial sensor) 10, its detection accuracy depends on the magnitude of mass of the movable weight portion 40. Therefore, the mass of the movable weight portion 40 must be increased.

### Additional Weight Portion

In the embodiment, therefore, the movable weight portion 40 is further provided with an additional weight portion formed in a different layer (the supporting substrate 11 in the embodiment) from the plurality of movable electrode portions 60 and the coupling portion 42 and connected to the coupling portion 42.

The additional weight portion 46 is disposed for increasing the mass that the coupling portion 42 alone cannot suffice in the limited occupied area, and preferably has the following dimensions compared to the coupling portion 42. First, a width L2 of the additional weight portion 46 in a longitudinal section (FIG. 2) perpendicular to the first direction A is greater than the width L1 of the coupling portion 42 in the longitudinal section (FIG. 2) perpendicular to the first direction A. This is because this can increase the mass of the additional weight portion 46. Second, the width L2 of the additional weight portion in the longitudinal section (FIG. 2) perpendicular to the first direction A is smaller than a total width L3 of the coupling portion 42 and the two movable electrode portions 61 on both sides of the coupling portion 42 in the longitudinal section (FIG. 2) perpendicular to the first direction A. This is because this does not increase the occupied area. Third, a height H2 of the additional weight portion 46 in the longitudinal section (FIG. 2) perpendicular to the first direction A is greater than a height H1 of the coupling portion 42 in the longitudinal section (FIG. 2) perpendicular to the first direction A. This can also increase the mass of the additional weight portion 46, and in addition, the height H1 of the plurality of movable electrode portions 60 formed in the same layer as the coupling portion 42 is advantageously reduced in view of the measures for the Brownian noise.

### Connection Portion

In the embodiment, a first connection portion 44 connecting the additional weight portion 46 with the coupling portion 42 can be further included. In this case, the hollow portion 70 extends to a region between the plurality of movable electrode portions 60 and the additional weight portion 46 and excluding the first connection portion 44. In this manner, when the additional weight portion 46 and the coupling portion 42 are connected via the first connection portion 44, the region between the plurality of movable electrode portions 60 and the additional weight portion 46 can be secured as the hollow portion 70. Therefore, the air between the fixed electrode portion 50 and the movable electrode portion 60 is also allowed to escape to the hollow portion 70 below the movable electrode portion 60 in FIG. 2, which can reduce the Brownian noise.

In addition to the first connection portion 44 as shown in FIG. 3, a second connection portion 48 connecting at least one (two in FIG. 3) movable electrode portion 61 of the plurality of movable electrode portions 60 with the additional weight portion 46 can be further included. With this configuration, even when inertial force other than that in the first direction A shown in FIG. 1 acts on the MEMS sensor, the additional weight portion 46 can be prevented from rolling with the first connection portion 44 as a fulcrum point in a longitudinal section shown in FIG. 3. Thus, even when inertial force other than that in the first direction A shown in FIG. 1 acts on the MEMS sensor 10, the facing area of the fixed electrode portion 50 and the movable electrode portion 60 does not fluctuate, making it possible to prevent inertial force other than that in the first direction A from being superimposed as noise.

In the example shown in FIG. 3, since the hollow portion 70 extends to the region between the plurality of movable electrode portions 60 and the additional weight portion 46 and excluding the first connection portion 44 and the second connection portion 48, the Brownian noise can be reduced similarly to the above.

### Elastically Deformable Portion

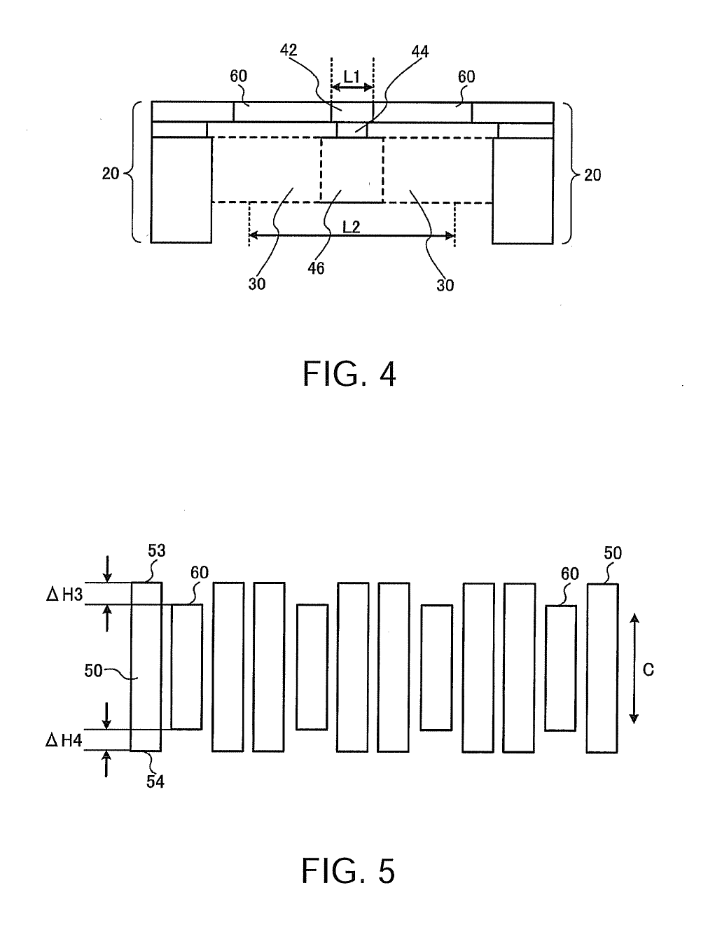

The elastically deformable portion 30 couples the movable weight portion 40 with the fixed portion 20 such that the movable weight portion 40 can be displaced along the first direction A. The elastically deformable portion 30 can be connected to one of the coupling portion 42 and the additional weight portion 46 that constitute the movable weight portion 40. FIG. 4 is a longitudinal sectional view of the MEMS sensor 10 including the elastically deformable portion 30 in FIG. 1. As shown in FIG. 4, the elastically deformable portion 30 is preferably connected to the additional weight portion 46. This is because the center of gravity of the movable weight portion 40 is positioned at the additional weight portion 46. The additional weight portion 46 at which the center of gravity is positioned is supported by the elastically deformable portions 30, so that even when inertial force other than that in the first direction A shown in FIG. 1 acts on the MEMS sensor 10, displacement of the movable weight portion 40 in directions other than the first direction A can be reduced.

As described above, the additional weight portion 46 has the height H2, and therefore, when the elastically deformable portion 30 is formed by the same process as that of the additional weight portion 46, the elastically deformable portion 30 has also the height H2, which is relatively high. In such case, for reducing the spring constant of the elastically deformable portion 30 to easily elastically deform, the elastically deformable portion 30 is bent or curved in a bellows shape for example, whereby the total length thereof is increased.

A spring constant K of the elastically deformable portion 30 is as follows.

K=Eh(W/L)³×1/N

E: Young's modulus in detected direction

h: spring thickness (=H2)

W: spring width

L: spring length

N: the number of folds

### Height Relationship Between Movable Electrode Portion and Fixed Electrode Portion

When a third direction C (refer to FIG. 2) perpendicular to the first direction A and the second direction B is defined as a center-of-gravity direction, one of the plurality of fixed electrode portions 50 and the plurality of movable electrode portions 60 each can have an upper margin portion and a lower margin portion respectively protruding upward and downward beyond the other of the plurality of fixed electrode portions 50 and the plurality of movable electrode portions 60.

As an example, FIG. 5 shows a case where each of the plurality of fixed electrode portions 50 has an upper margin portion 53 and a lower margin portion 54 respectively protruding upward and downward beyond the plurality of movable electrode portions 60. In this manner, when the fixed electrode portion 50 has the upper margin portion 53 and the lower margin portion 54, inertial force other than that in the first direction A is not superimposed as noise even if the inertial force other than that in the first direction A acts on the MEMS sensor 10. That is, even if the movable electrode portion 60 is displaced by rolling or the like in the vertical direction, one of the upper margin portion 53 and the lower margin portion 54 of the fixed electrode portion 50 faces the movable electrode portion 60. Therefore, the facing area of the fixed electrode portion 50 and the movable electrode portion 60 does not fluctuate. When the facing area of the fixed electrode portion 50 and the movable electrode portion 60 fluctuates, the fluctuation is detected as a capacitance change. However, this capacitance change can be prevented.

In this case, when the MEMS sensor 10 is installed at a predetermined place, a margin amount ΔH3 that the upper margin portion 53 of the fixed electrode portion 50 protrudes beyond the movable electrode portion 60 is desirably substantially equal to a margin amount ΔH4 that the lower margin portion 54 of the fixed electrode portion 50 protrudes beyond the movable electrode portion 60. As shown in FIG. 5, however, when the third direction C is defined as the center-of-gravity direction, it is preferable to consider deflection due to the own weight of the movable weight portion 40 and/or the movable electrode portion 60. As design values, therefore, the margin amount ΔH4 of the lower margin portion 54 can be set to be greater than the margin amount ΔH3 of the upper margin portion (ΔH3<ΔH4). As a result of this setting, at a maximum deflection point due to the own weight of the movable weight portion 40 and/or the movable electrode portion 60, the margin amount ΔH3 can be nearly equal to the margin amount ΔH4. The maximum deflection point due to the own weight of the movable weight portion 40 is presumably the movable electrode portion 60 corresponding to the intermediate position between the two elastically deformable portions 30 and 30 (that is, the position furthest from the elastically deformable portion 30) in FIG. 1. The maximum deflection point due to the own weight of the movable electrode portion 60 is presumably the free end thereof furthest from the base end at which the movable electrode portion 60 is coupled to the coupling portion 42. At a portion with a small deflection due to its own weight, the margin amount ΔH4 of the lower margin portion 54 remains greater than the margin amount ΔH3 of the upper margin portion in accordance with the design values. Also at the portion with a small deflection, the margin amounts ΔH3 and ΔH4 may be set so that one of the upper margin portion 53 and the lower margin portion 54 of the fixed electrode portion 50 faces the movable electrode portion 60 even if the movable electrode portion 60 is displaced by rolling or the like in the vertical direction.

The height relationship between the movable electrode portion 60 and the fixed electrode portion 50 is not limited to the sensor structures of the embodiment shown in FIGS. 1 to 4 but can be widely applied to a MEMS sensor having a movable electrode portion and a fixed electrode portion provided to face each other. That is, the height relationship can be widely applied to a MEMS sensor having a fixed portion, an elastically deformable portion, a movable weight portion coupled to the fixed portion via the elastically deformable portion and having a hollow portion formed therearound, a plurality of fixed electrode portions secured to the fixed portion to be arranged along a first direction and protruding along a second direction perpendicular to the first direction, and a plurality of movable electrode portions protrudingly formed from the movable weight portion along the second direction, provided to respectively face the plurality of fixed electrode portions, and arranged along the first direction.

### Configuration Example of Circuit Portion Connected to Acceleration Sensor

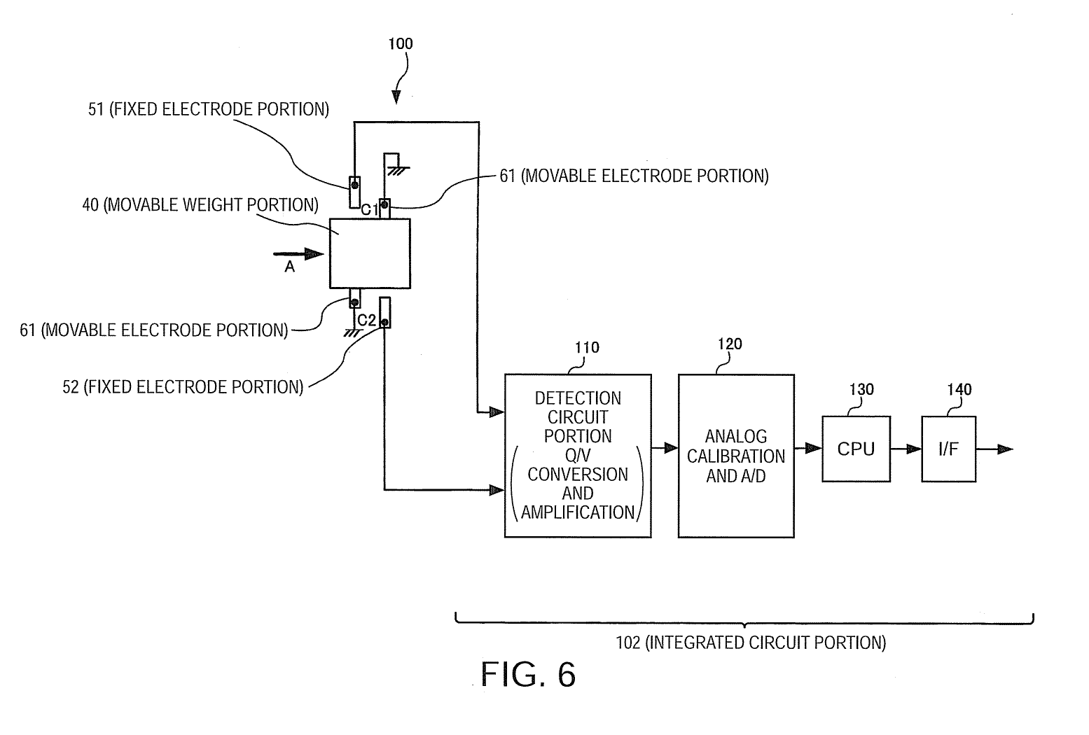

FIG. 6 shows a configuration example of a circuit portion connected to an electrostatic capacitive acceleration sensor 100 as the MEMS sensor 10. The acceleration sensor 100 has at least two sets of movable and fixed electrode pairs. FIG. 6 shows one movable electrode portion 61 and two fixed electrode portions 51 and 52 where they are different in installation location from FIG. 1 but have the same function. The movable electrode portion 61 and the fixed electrode portion 51 constitute a capacitor C1. The movable electrode portion 61 and the fixed electrode portion 52 constitute a capacitor C2. The potential of one electrode (movable electrode in this case) of each of the capacitors C1 and C2 is fixed at a reference potential (for example, a ground potential). The potential of the fixed electrode portion may be connected to a reference potential (for example, a ground potential).

A detection circuit portion 110 can include an amplifier circuit SA, an analog calibration and A/D conversion circuit unit 120, a central processing unit (CPU) 130, and an interface (I/F) circuit 140. However, this configuration is an example and is not restrictive. For example, the CPU 130 can be replaced by control logic, and the A/D conversion circuit can be disposed in the output stage of the amplifier circuit disposed in the detection circuit portion 110. The analog/digital conversion circuit and the central processing unit may be disposed in another integrated circuit in some cases.

When acceleration acts on the movable weight portion 40 in a state where the movable weight portion 40 is stopped, force due to the acceleration acts on the movable weight portion 40, changing each gap between the movable and fixed electrode pair. Assuming that the movable weight portion 40 moves in the first direction A in FIG. 6, the gap between the movable electrode portion 61 and the fixed electrode portion 51 increases, and the gap between the movable electrode portion 61 and the fixed electrode portion 52 decreases. Since the gap and the capacitance are in an inverse relationship, a capacitance value C1 of the capacitor C1 formed of the movable electrode portion 61 and the fixed electrode portion 51 decreases, and a capacitance value C2 of the capacitor C2 formed of the movable electrode portion 61 and the fixed electrode portion 52 increases.

The movement of charge occurs along with a change in capacitance value of the capacitors C1 and C2. The detection circuit portion 110 has a charge amplifier (Q/V conversion circuit) using, for example, a switched capacitor. The charge amplifier converts a minute current signal (charge signal) caused by the movement of charge into a voltage signal by sampling operation and integration (amplification) operation. A voltage signal (that is, a detected acceleration signal detected by the acceleration sensor) output from the charge amplifier is subjected to calibration processing (for example, adjustment of phase or signal amplitude, and further, low-pass filter processing may be performed) by the analog calibration and A/D conversion circuit unit 120, and thereafter converted from an analog signal to a digital signal.

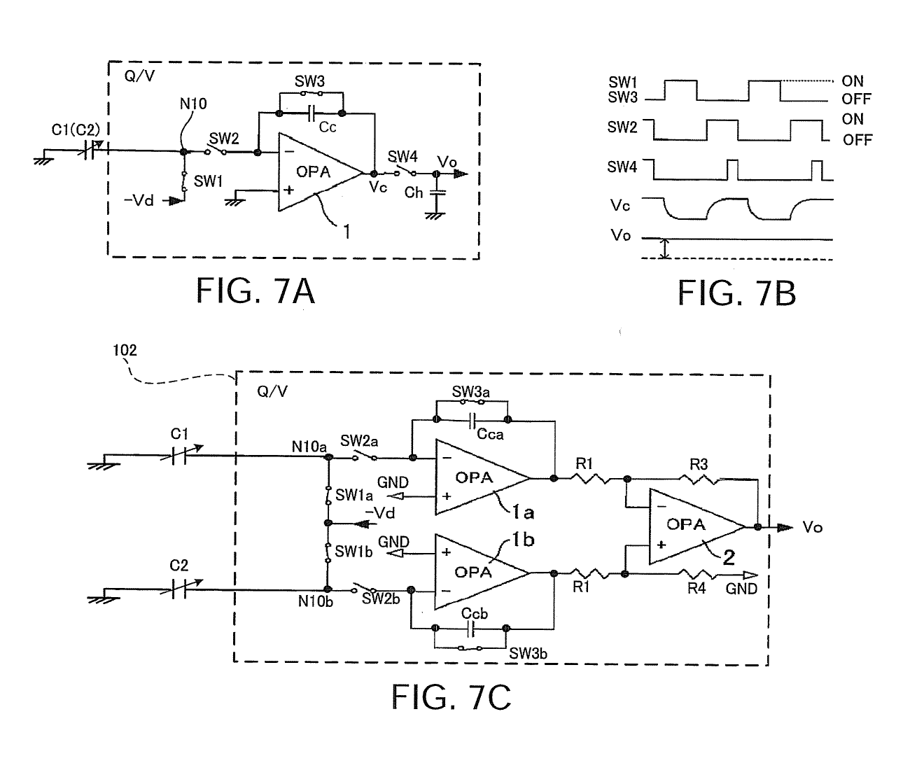

With reference to FIGS. 7A to 7C, exemplary configuration and operation of the Q/V conversion circuit will be described. FIG. 7A shows the basic configuration of the Q/V conversion amplifier (charge amplifier) using a switched capacitor. FIG. 7B shows voltage waveforms of respective parts of the Q/V conversion amplifier in FIG. 7A.

As shown in FIG. 7A, the Q/V conversion circuit basically has a first switch SW1 and a second switch SW2 (constituting a switched capacitor of an input part together with the variable capacitance C1 (or C2)), an operational amplifier OPA1, a feedback capacitance (integral capacitance) Cc, a third switch SW3 for resetting the feedback capacitance Cc, a fourth switch SW4 for sampling an output voltage Vc of the operational amplifier OPA1, and a holding capacitance Ch.

As shown in FIG. 7B, the on/off of the first switch SW1 and the third switch SW3 is controlled by a first clock of the same phase, and the on/off of the second switch SW2 is controlled by a second clock having an opposite phase from the first clock. The fourth switch SW4 is briefly turned on at the end of a period in which the second switch SW2 is turned on. When the first switch SW1 is turned on, a predetermined voltage Vd is applied to both ends of the variable capacitance C1 (C2), so that charge is accumulated in the variable capacitance C1 (C2). In this case, the feedback capacitance Cc is in a reset state (state of being short-circuited between both ends) because the third switch is in the on state. Next, when the first switch SW1 and the third switch SW3 are turned off, and the second switch SW2 is turned on, since the both ends of the variable capacitance C1 (C2) are at a ground potential, the charge accumulated in the variable capacitance C1 (C2) moves toward the operational amplifier OPA1. In this case, since the charge amount is stored, the relation of Vd·C1 (C2)=Vc·Cc is established. Accordingly, the output voltage Vc of the operational amplifier OPA1 is expressed by (C1/Cc)·Vd. That is, the gain of the charge amplifier is determined by the ratio between the capacitance value of the variable capacitance C1 (or C2) and the capacitance value of the feedback capacitance Cc. Next, when the fourth switch (sampling switch) SW4 is turned on, the output voltage Vc of the operational amplifier OPA1 is held by the holding capacitance Ch. Vo denotes the held voltage. The voltage Vo is the output voltage of the charge amplifier.

As shown in FIG. 6, differential signals from the two capacitors C1 and C2 are actually input to the detection circuit portion 110. In this case, a differential charge amplifier shown in FIG. 7C, for example, can be used as the charge amplifier. In the charge amplifier shown in FIG. 7C, in the input stage, a first switched-capacitor amplifier (SW1a, SW2a, OPA1a, Cca, and SW3a) for amplifying a signal from the variable capacitance C1 and a second switched-capacitor amplifier (SW1b, SW2b, OPA1b, Ccb, and SW3b) for amplifying a signal from the variable capacitance C2 are disposed. Respective output signals (differential signals) of the operational amplifiers OPA1a and OPA1b are input to a differential amplifier (OPA2 and resistances R1 to R4) disposed in the output stage. As a result, the output signal Vo amplified is output from the operational amplifier OPA2. The use of the differential amplifier provides an effect that base noise (common mode noise) can be removed.

The above-described configuration of the charge amplifier is an example, and the charge amplifier is not limited to the configuration. For the convenience of description, only the two sets of movable and fixed electrode pairs are shown in FIGS. 6 and 7. However, this is not restrictive. The number of electrode pairs can be increased according to a required capacitance value. Actually, from several tens to several hundreds of electrode pairs are disposed, for example.

### Manufacturing Method

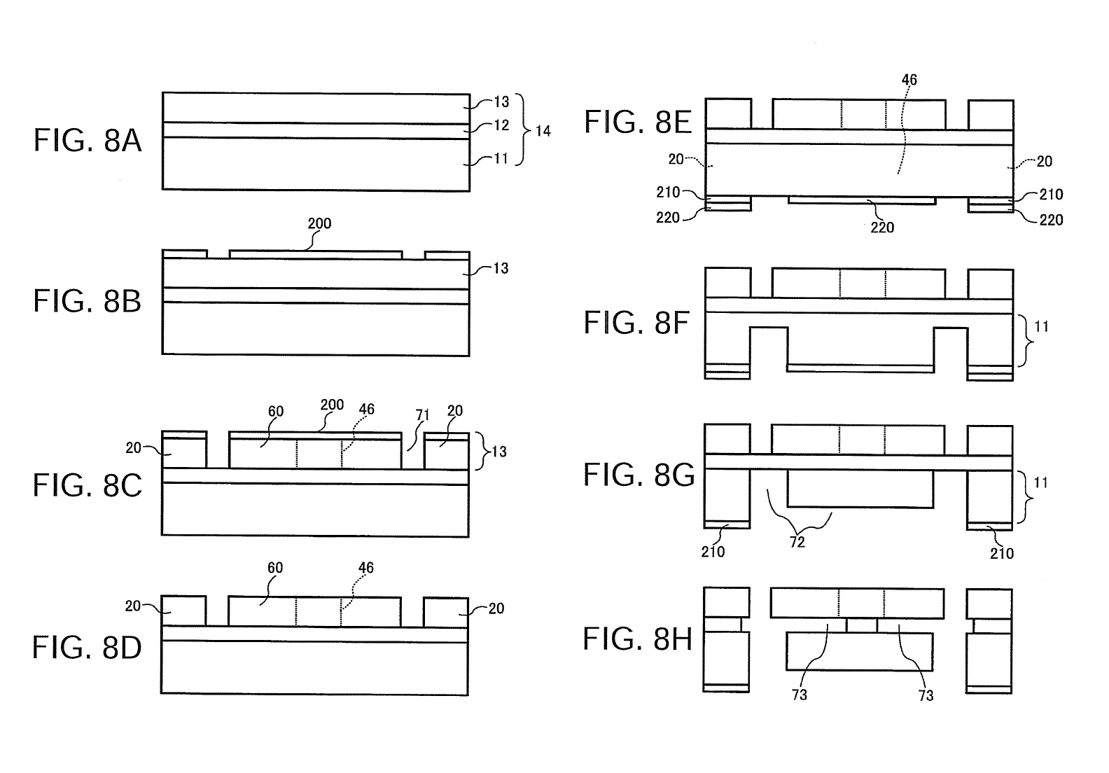

FIGS. 8A to 8H show the manufacturing process of the MEMS sensor 10 shown in FIG. 1. FIG. 8A shows a stacked structure used for manufacturing the MEMS sensor 10. In the embodiment, the SOI substrate 14 having the supporting substrate (silicon) 11, the intermediate layer (SiO₂) 12, and the functional layer (doped silicon) 13 is used. However, the stacked structure may be configured by stacking the intermediate layer 12 and the functional layer 13 on the supporting substrate 11.

FIGS. 8B to 8D show a patterning step (first step) for the functional layer 13. First as shown in FIG. 8B, a first mask 200 is formed on the functional layer 13 in a region not subjected to etching in the first step. The first mask 200 may be a resist material formed by a photolithography step. Next as shown in FIG. 8C, the functional layer 13 in a region not covered with the first mask 200 is anisotropically etched. When the functional layer 13 is silicon, a publicly known etchant suitable for anisotropically etching silicon is selected. With first hollow portions 71 formed in this case, respective outlines, as viewed in plan, of the fixed portions 20, the elastically deformable portions 30, the plurality of fixed electrode portions 50, the plurality of movable electrode portions 60, and the coupling portion coupling the plurality of movable electrode portions, all formed of the functional layer 13, can be shaped. In FIG. 8D, the first mask 200 is removed.

FIGS. 8E to 8G show a patterning step (second step) for the supporting substrate 11 (silicon). In the second step, the supporting substrate 11 is etched in two steps. As shown in FIG. 8E, therefore, a second mask 210 and a third mask 220 are formed on the supporting substrate 11 in a region not subjected to etching in the second step. In a region corresponding to the fixed portion 20, the second mask 210 and the third mask 220 are formed in an overlapped manner. In a region corresponding to the additional weight portion 46, only the third mask 220 is formed. The second mask 210 and the third mask 220 may be a resist material formed by a photolithography step, or SiO₂, Si₃N₄, metal, or the like. Next as shown in FIG. 8F, the supporting substrate 11 in a region not covered with the second mask 210 and the third mask 220 is anisotropically etched partially. Thereafter, in a state where only the third mask 220 is removed, the supporting substrate 11 in a region not covered with the second mask 210 is anisotropically etched. In this case, the intermediate layer 12 serves as an etching stop layer. When the supporting substrate 11 is silicon, a publicly known etchant suitable for anisotropically etching silicon is selected. With a second hollow portion 72 formed in this case, respective outlines, as viewed from the back side, of the fixed portions 20 and the additional weight portion 46, both formed of the supporting substrate 11, are shaped.

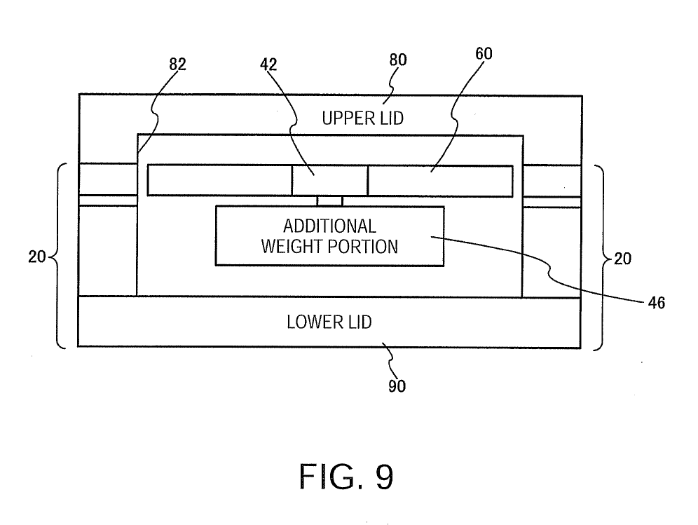

Due to the two-step etching, the bottom surface of the additional weight portion 46 is recessed inward more than the bottom surface of the fixed portion 20. Thus as shown in FIG. 9, even when the MEMS sensor 10 is covered with an upper lid 80 and a lower lid 90, a structure in which the additional weight portion 46 is easily displaced without contacting the lower lid 90 can be secured. However, the bottom surface of the additional weight portion 46 may be flush with the bottom surface of the fixed portion 20 by only one-step etching. In this case, a step portion 82 disposed in the upper lid 80 shown in FIG. 9 is attached also to the lower lid 90, so that a hollow portion may be secured below the additional weight portion 46. Moreover, the second step can be carried out prior to the first step.

In a third step after the first and second steps as shown in FIG. 8H, the intermediate layer 12 other than that to be left in a region of the first connection portion 44 (and further the second connection portion 48) connecting the coupling portion 42 with the additional weight portion 46 and in a region of the fixed portion 20 is isotropically etched. When the intermediate layer 12 is SiO₂, a publicly known etchant suitable for isotropically etching SiO₂ is selected. Below the coupling portion 42, an etchant supplied from the first hollow portions 71 on both sides of the coupling portion 42 is introduced, so that the intermediate layer 12 is isotropically etched. However, the width L1 of the coupling portion 42 is greater than the shorter width of the fixed electrode portion 50 and the movable electrode portion 60. Therefore, although third hollow portions 73 are formed below the fixed electrode portion 50 and the movable electrode portion 60, the first connection portion 44 is left below the coupling portion 42. Similarly, when the second connection portion 48 shown in FIG. 4 is formed, the width of the movable electrode portion 60 at a portion connected to the second connection portion 48 may be widened.

### 2. Second Embodiment

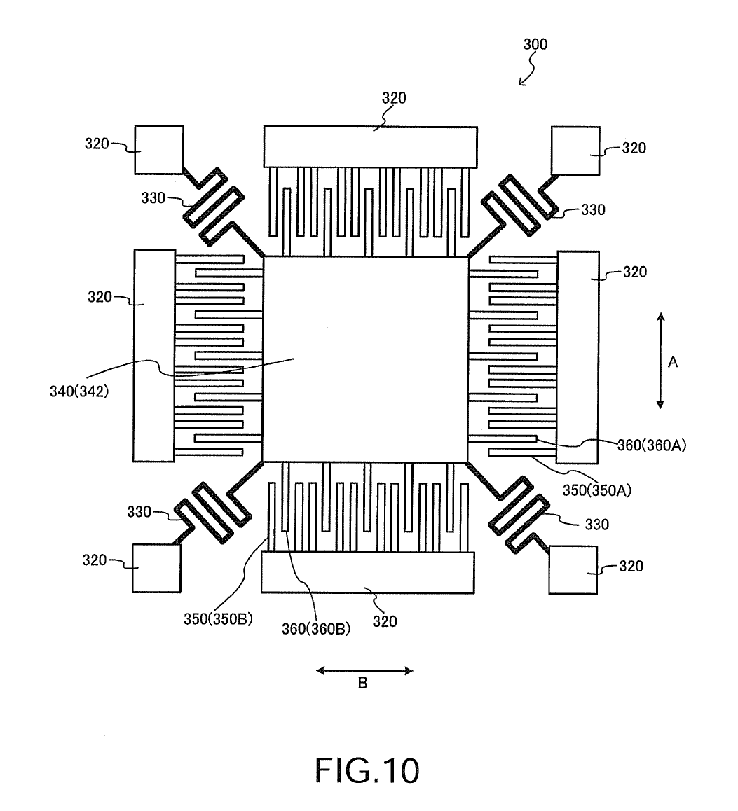

FIG. 10 is a plan view of a two-axis acceleration sensor (MEMS sensor) 300 according to a second embodiment of the invention. As shown in FIG. 10, the MEMS sensor 300 can have fixed portions 320, elastically deformable portions 330, a movable weight portion 340, fixed electrode portions 350, and movable electrode portions 360. The fixed portion 320 can be formed in a frame shape so as to surround the elastically deformable portions 330, the movable weight portion 340, the fixed electrode portions 350, and the movable electrode portions 360 from all four sides. The movable weight portion 340 is coupled to the fixed portions 320 via the elastically deformable portions 330, and has hollow portions 370 formed therearound.

The fixed electrode portion 350 has first fixed electrode portions 350A secured to the fixed portion 320 to be arranged along the first direction A and protruding along the second direction B perpendicular to the first direction A. The fixed electrode portion 350 further has second fixed electrode portions 350B secured to the fixed portion 320 to be arranged along the second direction B and protruding along the first direction A. The movable electrode portion 360 has first movable electrode portions 360A protrudingly formed from the movable weight portion 340 along the second direction B, provided to face the fixed electrode portion 350, and arranged along the first direction A. The movable electrode portion 360 further has second movable electrode portions 360B protrudingly formed from the movable weight portion 340 along the first direction A, provided to face the fixed electrode portion 350, and arranged along the second direction B.

In this manner, since the movable electrode portion 360 is disposed on four sides of a coupling portion 342 as a part of the movable weight portion 340, the two-axis acceleration sensor 300 does not have a fish-bone shape like the one-axis acceleration sensor 10 in FIG. 1 but is formed in substantially a square shape. For reducing the Brownian noise, however, the height (corresponding to the height H1 in FIG. 2) of the fixed electrode portion 350 and the movable electrode portion 360 cannot be increased. As shown in FIG. 2 or 3, therefore, the additional weight portion is coupled to the coupling portion 342 via the first connection portion (and further the second connection portion) to compensate for insufficient mass of the movable weight portion 340 (a longitudinal sectional view is omitted because it is similar to FIG. 2 or 3). In this case, the relationship among the dimensions L1 to L3 and H1 and H2 shown in FIG. 2 can also be applied similarly to the two-axis acceleration sensor 300 in FIG. 10. Moreover, the modified example shown in FIG. 4 or 5 can also be applied similarly to the two-axis acceleration sensor 300 in FIG. 10.

The elastically deformable portions 330 couple the movable weight portion 340 to the fixed portions 320 so that the movable weight portion 340 can be displaced in two axes of the first direction A and the second direction B. As shown in FIG. 10 for example, the elastically deformable portions 330 are coupled to four corners of the movable weight portion 340 (the coupling portion 342) having a square shape. Also in this case, the elastically deformable portion 330 is formed in a bellows shape, for example, for reducing the spring constant thereof.

Connecting, as the circuit portion shown in FIG. 6, a first circuit portion that detects acceleration in the first direction A and a second circuit portion that detects acceleration in the second direction B to the two-axis acceleration sensor 300 makes it possible to detect acceleration in two axes.

### 3. Third Embodiment

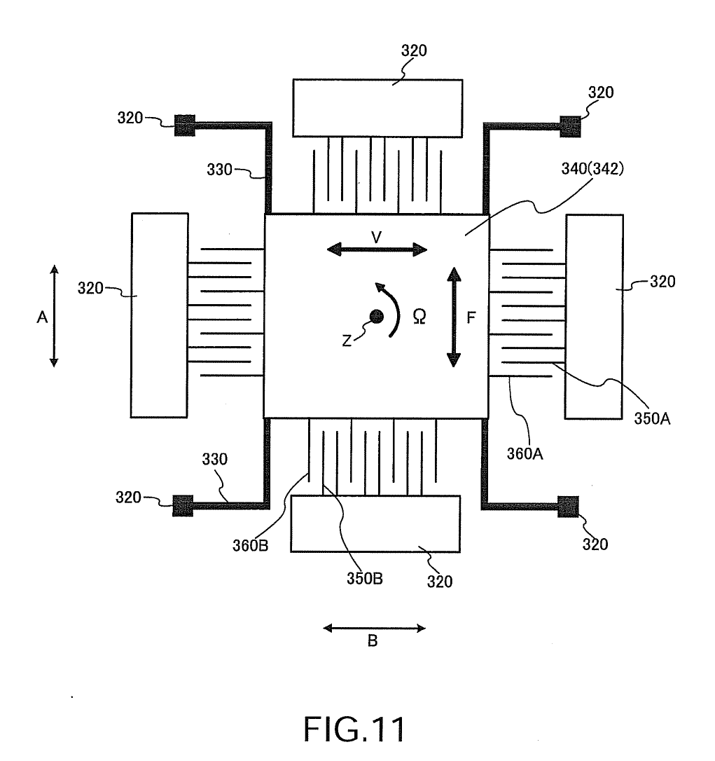

FIG. 11 is a plan view of a gyro sensor 400 according to a third embodiment of the invention. The gyro sensor 400 has the same structure as that of the two-axis acceleration sensor 300 shown in FIG. 10. Therefore, the same reference numerals and signs as those in FIG. 10 are assigned to the constituents of the gyro sensor 400, and the detailed description thereof is omitted. However, the gyro sensor 400 is different in detection principle from the two-axis acceleration sensor 300 shown in FIG. 10.

The gyro sensor 400 causes the Coulomb force to act between the second fixed electrode portion 350B and the second movable electrode portion 360B, thereby vibrating the movable weight portion 340 in the second direction B at a constant rate. In this sense, the second fixed electrode portion 350B and the second movable electrode portion 360B constitute a drive electrode.

In a state where the movable weight portion 340 vibrates in the second direction B at a constant rate, when an angular velocity Ω about a Z-axis (axis perpendicular to the paper surface of FIG. 11) is applied to the movable weight portion 340, a Coriolis force F is generated along the first direction A. When the movable weight portion 340 moves along the first direction A with the Coriolis force F, the gap between the first fixed electrode portion 350A and the first movable electrode portion 360A changes, and the capacitance change is detected by the circuit portion in FIG. 6. Thus, the direction and magnitude of the angular velocity Ω can be detected (refer to JP-A-11-248739).

In this manner, the gyro sensor 400 is different from the two-axis acceleration sensor 300 shown in FIG. 10 only in that one electrode pair 350B and 360B of the two-axis acceleration sensor 300 is used as drive electrodes and the other electrode pair 350A and 360A is used as detection electrodes, and it has substantially the same structure as that of the two-axis acceleration sensor 300. Accordingly, the invention can also be applied to the gyro sensor 400 similarly to the two-axis acceleration sensor 300.

Although some embodiments have been described, those skilled in the art should readily understand that many modifications may be made without substantially departing from the novel matter and effects of the invention. Accordingly, those modified examples are also included in the scope of the invention. For example, a term described at least once with a different term with a broader sense or the same meaning in the specification or the accompanying drawings can be replaced with the different term in any part of the specification or the accompanying drawings.

For example, the MEMS sensor according to the invention is not necessarily applied to an electrostatic capacitive acceleration sensor or a gyro sensor but can be applied to any inertial sensor as long as it detects a change in electrostatic capacitance due to the movement of a movable weight portion. For example, the MEMS sensor can also be applied to a pressure sensor that causes a silicon diaphragm to deform with air pressure in a cavity (hollow chamber) and detects a change in electrostatic capacitance (or a change in resistance value of a piezoresistance etc.) caused by the deformation.

The entire disclosure of Japanese Patent Application No. 2009-267794, filed Nov. 25, 2009 is expressly incorporated by reference herein.

What is claimed is:

1. A MEMS sensor comprising:
a fixed portion;
an elastically deformable portion;
a movable weight portion coupled to the fixed portion via the elastically deformable portion, the movable weight portion including a coupling portion;
a plurality of fixed electrode portions arranged in a first direction and protruding in a second direction perpendicular to the first direction; and
a plurality of movable electrode portions protruding from the coupling portion in the second direction, provided to respectively face the plurality of fixed electrode portions, and arranged in the first direction, wherein
the movable weight portion comprises an additional weight portion connected to the coupling portion.

2. The MEMS sensor according to claim 1, further comprising a first connection portion connecting the additional weight portion with the coupling portion.

3. The MEMS sensor according to claim 1, further comprising a second connection portion connecting at least one of the plurality of movable electrode portions with the additional weight portion.

4. The MEMS sensor according to claim 1, wherein
a width of the additional weight portion in a longitudinal section in the second direction is greater than a width of the coupling portion in the longitudinal section in the second direction.

5. The MEMS sensor according to claim 1, wherein
the movable electrode portion protrudes from both edges of the coupling portion in the second direction, and
a width of the additional weight portion in a longitudinal section in the second direction is smaller than a length in the second direction from an end of the movable electrode portion protruding from one edge of the coupling portion to an end of the movable electrode portion protruding from the other edge of the coupling portion.

6. The MEMS sensor according to claim 1, wherein
a height of the additional weight portion in a longitudinal section in the second direction is greater than a height of the coupling portion in the longitudinal section in the second direction.

7. The MEMS sensor according to claim 1, wherein
the elastically deformable portion couples the fixed portion with the additional weight portion.

8. The MEMS sensor according to claim 1, wherein
when a direction perpendicular to the first direction and the second direction is defined as a third direction, one of the fixed electrode portion and the movable electrode portion is longer in the third direction than the other.

9. The MEMS sensor according to claim 8, wherein
one of the plurality of fixed electrode portions and the plurality of movable electrode portions each comprise an upper margin portion and a lower margin portion respectively protruding upward and downward beyond the other in the third direction, and partially comprise a region where a protruding amount of the lower margin portion is greater than a protruding amount of the upper margin portion.

10. An electronic apparatus comprising the MEMS sensor according to claim 1.

11. A method of manufacturing a MEMS sensor, comprising:
preparing a supporting substrate having an intermediate layer and a functional layer stacked on the intermediate layer;
applying etching to the supporting substrate to form a first hollow portion from a surface of the functional layer to a surface of the intermediate layer, to thereby define a fixed portion, a movable weight portion, an elastically deformable portion coupling the fixed portion with the movable weight portion, a fixed electrode portion, and a movable electrode portion facing the fixed electrode portion and protruding from the movable weight portion;
etching the supporting substrate from a surface of the supporting substrate opposite to the surface where the intermediate layer and the functional layer are formed to form a second hollow portion at a position overlapping the first hollow portion as viewed in plan, to thereby define an additional weight portion; and
etching the intermediate layer via at least one of the first hollow portion and the second hollow portion, to thereby form a first connection portion connecting the movable weight portion with the additional weight portion.
